(19) United States
(12) Patent Application Publication
(10) Pub. No.: US 2013/0300410 A1
(43) Pub. Date: Nov. 14, 2013

(54) Method for fast spin-echo MRT imaging

(71) Applicant: MAX-DELBRUECK- CENTRUM FUER MOLEKULARE MEDIZINE, (US)

(72) Inventors: Thoralf Niendorf, Aachen (DE); Fabian Hezel, Berlin (DE); Sabrina Klix, Biesenthal (DE)

(21) Appl. No.: 13/853,825

(22) Filed: Mar. 29, 2013

(30) Foreign Application Priority Data
Mar. 30, 2012 (EP) 12162485.2
Apr. 2, 2012 (EP) 12162861.4
Jun. 12, 2012 (EP) 12171685.6

(51) Int. Cl. G01R 33/565

(52) U.S. Cl. CPC G01R 33/56509
USPC 324/307

(57) ABSTRACT

The invention relates to a method for fast autocalibrated spin-echo MRT imaging by means of independently coded echo groups, wherein one of the two echo groups is used for recording a reference data set or a training data set, while the other echo group is recorded in subsampled manner.

### CROSS REFERENCE TO RELATED APPLICATIONS

This application claims priority to European application nos. EP 12162485.2, filed Mar. 30, 2012; EP 12162861.4, filed Apr. 2, 2012 and EP 12171685.6, filed Jun. 12, 2012, which are incorporated herein by reference in their entirety.

### FIELD OF THE INVENTION

The invention is directed at a method for a fast, autocalibrated Spin-Echo Magnetic Resonance Tomography (MRT) technique by via independently coded and reconstructed echo groups.

Magnetic resonance tomography is an imaging method. Cardiovascular magnetic resonance (MR) imaging requires fast imaging techniques to reduce movement artifacts and to shorten the examination time.

### BACKGROUND OF THE INVENTION

Clinical MR imaging is based on the excitation of hydrogen protons. According to “Bohr's atom model” the proton of a hydrogen atom is positively charged and a negatively charged electron orbits around the proton.

The proton of a hydrogen atom possesses an inherent rotary impulse, called spin. The spin generates a magnetic dipole, therefore the hydrogen atom aligns itself in a magnetic field and can be excited by an electromagnetic high-frequency field. The protons align themselves along a static magnetic field B₀ and precess. The precession movement possesses a characteristic frequency, the Larmor frequency, which is proportional to the intensity of the magnetic field (Weishaipt, Kächeli and Marincek, Wie funktioniert MRT? [How does MRT work?] Heidelberg: Springer-Verlag, 2009. p. 1-23).

The first step in MR imaging is layer-selective excitation. During excitation by means of a high-frequency impulse, a gradient field in the corresponding direction is additionally produced, and therefore the precession frequency along this direction varies. It is possible to select layers of an object to be imaged in defined manner, by changing the local magnetic field intensity, and to generate a corresponding 2D image of this object. After excitation with corresponding gradient fields, the magnetic field possesses a gradient—a rising incline—along the Z direction. Each layer along the Z direction is given its own frequency. The Larmor frequency only excites the corresponding layer (Weishaipt, Kächeli and Marincek, 2009).

Adjacent layers are not excited, because the frequency of the spin (rotation frequency) does not correspond to the Larmor frequency and no resonance is generated.

The layer thickness is defined by the gradient intensity. After excitation of a layer, the electromagnetic signals are measured. These signals are a mixture of different frequencies that are emitted by different volume elements. For spatial allocation of the signals, further coding of the Y and X dimension is necessary.

The location coding that follows the layer selection is restricted to the selected layer. This happens by means of adding additional gradient fields to determine the individual data points of the X and Y coordinates. Location coding of the MR signal within the excited layer is based on break-down of the image contents into individual location frequency components. A phase coding gradient is built up along the Y direction. The gradient possesses a rise along the Y direction. The protons are already oriented, by means of the layer selection, and rotate in the X-Y plain. Because of the added phase coding gradients, the protons at the higher Larmor frequency rotate faster than protons at a lower frequency. A phase shift of the protons occurs. Each line of the defined layer can be clearly identified by means of its phase. The signal is frequency-coded with a frequency gradient G_{X} along the X coordinate. The protons behave in the same manner as in the phase coding. By means of the superimposition of phase and frequency coding, each volume element (voxel) can be clearly localized. The gradients G_{Z}, G_{Y} and G_{X} are superimposed with the main magnetic field B₀ (Weishaipt, Kächeli and Marincek, 2009).

The received signals correspond to a line in the k space. The measurement is repeated with a changed amplitude of the phase coding gradient G_{Y}, in each instance, thereby creating a further line in the k space. The slice is obtained by means of an inverse two-dimensional (2D) Fast-Fourier Transformation of the data.

A sequence is a combination of a temporal sequence of high-frequency pulses (of 90° and 180° pulses) and gradient fields having a corresponding intensity, which are generated multiple times per second in a predetermined order. The spin-echo sequence is relatively insensitive to the heterogeneity of the B₀ field. The sequence is based on a sequence of a 90° impulse and a 180° impulse. Free Induction Decay (FID) represents the induction decay of the MR signal. After a 90° impulse, the spins precess in phase. They fan out in the X-Y plane and run away from one another at different speeds (dephasing). After a running time of τ, a 180° impulse is generated. The spins rotate by 180° about the Y axis. They come back into phase (rephasing). After a running time of 2τ the spin-echo signal reaches its maximum, afterward the spin-echo decreases again. This time period is referred to as echo time (TE) (Magnete, Spins and Resonanzen [Magnets, Spins and Resonances], Erlangen: Siemens AB (Ed.) 2009).

Cardiovascular MR imaging requires a very fast data recording speed, in order to minimize movement artifacts of the heart. Synchronization with the heart cycle is required to reduce the influence of contraction on the image quality. Real-time imaging is only possible with limited image quality (Strohm, Bernhard, Niendorf: Kardiovaskuläre MRT in der Praxis [Cardiovascular MRT in Practice]. Munich: Urban and Fischer, 2006. p. 3-17). Segmented acquisition of MR data allows minimization of the artifacts caused by contraction and blood flow. In this connection, data acquisition takes place over multiple heart cycles. In each heart cycle, only a limited number of k space data is recorded. At reduced resolution, video display (CINE-view) of the contracting heart is possible. Three data lines are recorded per heart cycle and heart phase, in each instance, until the raw data in the k space have been completely drawn up. The 2D image is obtained using inverse Fast-Fourier-Transformation.

MR imaging can be accelerated using two fundamentally different methods. Fast imaging techniques acquire multiple echoes within a sequence. The turbo-spin-echo sequence (TSE) is presented as a fast sequence. The second method is based on reduced recording of data lines. Folding artifacts that require correction result from subsampling.

Turbo-spin-echo sequences (TSE) are based on multiple refocusing (echo train) of the initial excitation, in order to create a complete image. An echo train is generated by means of a basic excitation with a 90° pulse and a subsequent train of 180° pulses. Each echo of the series is given a different phase coding and fills a line of the raw data matrix. The maximal time gain determines the length of the echo train. The shorter the echo train, the fewer the image points that can be recorded (Weishaipt, Kächeli and Marincek, 2009).

In the turbo-spin-echo sequence, stimulated echoes occur starting with the second echo of the echo train. These have the usual echoes superimposed on them. The read-out gradients were adapted accordingly, so that the echoes were pushed apart from one another, so that during data acquisition, two echoes are present in a k space line, in each instance. The centers of the echoes lie at ¼ and ¾ of the acquisition window.

Four echoes are generated by means of four high-frequency impulses at 180° each. The G_{Y} gradient must be generated anew for each echo, at a changed amplitude, in each instance. With the different phase coding, four lines are obtained in the k space (Weishaipt, Kächeli and Marincek, 2009). The data are set down in segments, using this sequence.

Sensitivity coding (SENSE) is a method of parallel imaging. It is based on simultaneous signal detection with multiple reception coils. The reception coils are placed next to one another and close to the body surface. The date recording time can be shortened by using multiple coils, because additional location data are present because of the corresponding coil arrangement. These are used for reconstruction of the folding that occurs, (Preussmann et al. SENSE: Sensitivity Encoding for FAST MRI, Zurich, Switzerland: 1999).

The measurement time is reduced accordingly by recording only every second, fourth, or eighth data line in the k space, in each instance (=SENSE Factor 2, 4 or 8). By means of reducing the sampling density in the phase coding direction, the image field (=Field of View, FOV) is reduced by the corresponding factor (Noll and Sutton; Role of parallel imaging in high field functional MRL Michigan: Department of Biomedical Engineering, 2011). In the images, the reduced recording leads to typical folding in of projecting image portions.

Cardiovascular diseases are the most frequent causes of death worldwide. In 2011, about 41 percent of the total of 858,768 deaths in Germany were caused by cardiac infarction or other cardiovascular diseases. Cardiovascular MR imaging is a slice imaging method that can show the heart without using X-rays or radioactive substance, in any desired orientation.

An MRT of the heart requires fast imaging techniques, in order to minimize movement artifacts caused by heart movement and to be able to conduct data acquisition within clinically acceptable time periods. The duration of an individual MR data acquisition depends on the required spatial and temporal resolution of the images and can extend over multiple heartbeats.

Anatomical MR imaging of the heart and thoracic blood vessels predominantly takes place with black blood MR imaging techniques (black blood). Black blood MR techniques generally use what are called fast spin-echo techniques (English: FSE-Fast-Spin Echo). These are characterized in that a train of refocusing pulses refocuses the magnetization after excitation, and these can be read out multiple times, while the signal dies down, using location coding (technically: phase coding). FSE techniques can be designed both as one-shot methods and as segmented methods.

In anatomical imaging of the heart, it is necessary for the person being examined or the living thing being examined must hold his/her/its breath for the duration of data recording. One or more slice images are recorded per phase of holding the breath. 2D MRT imaging requires about 10 slice images to cover the entire heart. This leads to long examination times of 8-14 minutes. Therefore there is a need for accelerating the imaging. For example, an acceleration factor of 2 would cut the recording time in half.

Alternatively, imaging can take place with free respiration. To compensate the influences of respiratory movement on image quality, trigger or navigator techniques are used. These reduce the degree of effectiveness or the efficiency of image recording, and therefore can also benefit from any form of acceleration or improvement in the degree of effectiveness.

One possibility of acceleration is parallel imaging. This includes approaches that utilize the B1 intensity profiles of HF coils as a supplemental form of location coding. Because parallel imaging violates the Nyquist theorem, suitable methods for unfolding the subsampled data must be used. These include the image-based reconstruction approach SENSE (Preussmann et al. SENSE: sensitivity encoding for fast MRI. Magnetic Resonance in Medicine, 1999. 42(5): p. 952-62) and also the reconstruction approach based on k space data, SMASH (Sodickson and Manning, Simultaneous acquisition of spatial harmonics (SMASH): Fast imaging with radiofrequency coil arrays. Magnetic Resonance in Medicine, 1997. 38(4): p. 591-603) and GRAPPA (Griswold et al., Generalized Autocalibrating Partially Parallel Acquisitions (GRAPPA). Magnetic Resonance in Medicine, 2002. 47(6): p. 1202-1210). Both methods require determining the B1 intensity profiles of high-frequency (HF) coils. To create these reference data, non-accelerated, low-resolution data that are, however, sampled completely and at regular density are recorded. These reference data (English: reference scan) can be carried out separately (English: external reference scan) or as part of the accelerated data acquisition (English: self-calibration).

In addition, there are acceleration techniques in which data are subsampled along the time and space axis, what is called the k-t approach (k-t BLAST) (Tsao, Boesiger, and Pruessmann, k-t BLAST and k-t SENSE: Dynamic MRI with high frame rate exploiting spatiotemporal correlations. Magnetic Resonance in Medicine, 2003. 50(5): p. 1031-1042). Of course these techniques apply only for time series. Reconstruction and unfolding of these data takes place on the basis of non-accelerated training data that have low spatial resolution but are sampled completely, and detect the spatiotemporal relationship of the data of a time series. The training data can be recorded separately or nested simultaneously with the subsampled data.

To avoid incorrect registration between reference data or training date and the accelerated data set, the approach of autocalibration is preferred over an external reference scan. Likewise, real-time or time-nested recording of training data is preferred over separate recording of training data. Time-nested recording of training data can, however, lead to greater time loss than recording of training data. For clinical use, accelerated imaging is required so that the recording can be made within a clinically acceptable time.

There remains a need in the art for a method that does not demonstrate the disadvantages or defects of the state of the art, and with which accelerated imaging is achieved.

### SUMMARY OF THE INVENTION

In certain embodiments of the invention, this need and/or other needs are addressed.

In a first preferred embodiment, the invention relates to a magnetic resonance tomography (MRT) method, wherein

a) after basic excitation and a series of high-frequency refocusing pulses according to the spin-echo principle, two echo groups occur, wherein

b) the two echo groups are phase-coded independent of one another, and wherein

c) reconstruction takes place for the two echo groups, independent of one another.

The independent phase coding of the echo groups may be achieved via implementation of independent gradients along the phase coding direction.

One of the two echo groups may be used for recording a reference data set or a training data set, and the other echo group may be recorded in subsampled manner.

The reference data set or training data set may be used for autocalibration.

The echo groups may be used to generate images having different contrasts or images having the same contrasts with different weighting.

One echo group may be used to record a fat image, and the other echo group may be used to record a water image.

One echo group may experience a Cartesian form of phase coding, while the other echo group may experience non-Cartesian forms of phase coding, preferably spiral-shaped, radial or other arbitrary forms of k-space trajectories.

One echo group may be subsampled and reconstructed by means of parallel imaging, preferably SENSE or GRAPPA.

The subsampled echo group may be reconstructed using regularly sampled training data by means of the k-t approach or any other form of reconstruction technique.

One echo group may be used as a navigator echo or phase echo for recording movements or movement states, while the other echo group may serve for the collection of image data.

One echo group may be used to sample specific segments of the k space, while the other echo group may sample other segments of the k space.

The first echo group may be an odd echo group, and the second echo group may be an even echo group.

The above method according to the invention is characterized, in particular, by fast spin-echo MRT imaging. The invention is based on the Fast-Spin-Echo technique (FSE). In this technique, a train of refocusing pulses and data recording windows is preferably carried out after basic excitation.

It is true that in the state of the art, the use of the split-echo technique is described with identical phase coding and reconstruction for both echo groups, but the two echo groups are not considered independent of one another. The split-echo approach uses the same phase coding and reconstruction for echo group 1 and echo group 2.

The invention particularly takes advantage of the fact that in FSE techniques, spin-echoes and stimulated echoes occur. Depending on the number of refocusing pulses that the echo groups experience, in each instance, the echo groups are preferably classified as even and odd echoes. These appear in the center of the data recording window in the basic variant of the FSE technique, and interfere positively with one another there.

Phase coding in the sense of the invention is preferably a method for defining the lines of the measurement matrix. A magnetic field gradient is switched between the HF excitation pulse and reading out of the MR signal, for a short time, which gradient imposes a phase shift on the spins from line to line. For complete measurement of a slice, 256 or 512 phase coding steps, for example, have to occur, depending on the matrix. The subsequent Fourier-Transformation can assign the different phasing back to the corresponding lines.

During refocusing, the spins are brought back into phase.

### BRIEF DESCRIPTION OF THE FIGURES

FIG. 1 shows a preferred embodiment of the autocalibrated split-echo FSE (SCSE-FSE) technique, as an example. The two echo groups are phase-coded and reconstructed independent of one another. The centers of the echoes lie at about ¼ and ¾ of the acquisition window in this embodiment, but can be selected as desired, in terms of their position in the acquisition window, as long as they do not interfere with one another. In contrast to a conventional FSE sequence, the even and odd echo groups are separated and phase-coded independently.

FIG. 2 shows an enlarged view of a k-space cell, in order to illustrate the separation of the two echo groups. One echo group is generated for the coil sensitivity map (sensitivity map). The other group is used to generate subsampled data. Therefore one echo group serves for the reference data set (left), the second echo group serves for the accelerated data set (right). The echo groups can also be used as radial phase coding left and spiral phase coding right, navigator left and image data set, or Segment 1 k-space left and Segment 2 k-space right.

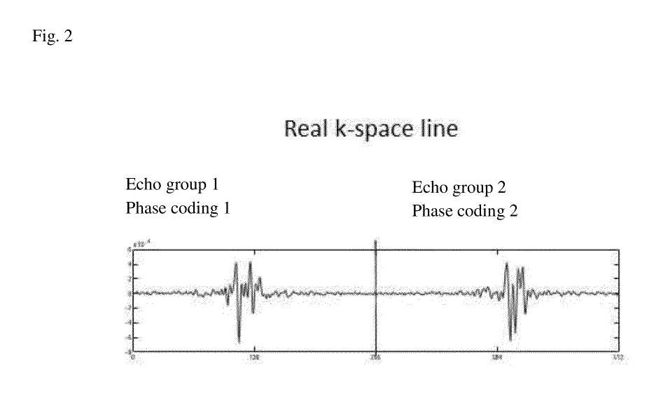

FIG. 3 shows the reference map of the left echo group in the case of a four-channel coil. A phantom is shown. The figure shows the sensitivity profile of the individual coils. The solid lines represent the greatest signal intensity.

FIG. 4 shows a reduced FOV of the right echo group with the acceleration factor R=2. The image represents the four individual coil images. Folding in the image region comes about as the result of recording of only every other k-space line. Using the reference map, the image can be unfolded with a linear equation system, and reconstructed to yield a complete image.

FIG. 5 shows a completely reconstructed image with acceleration factor R=2. The image was reconstructed with two independent echo groups.

FIG. 6 shows a sensitivity profile produced using the example of the heart. For this purpose, the echoes in the center of each k-space line were separated by means of suitable processing of the raw data. The left data set served as a reference map for the sensitivity profile. The 32 individual coil images shown have a resolution of 270×256 pixels.

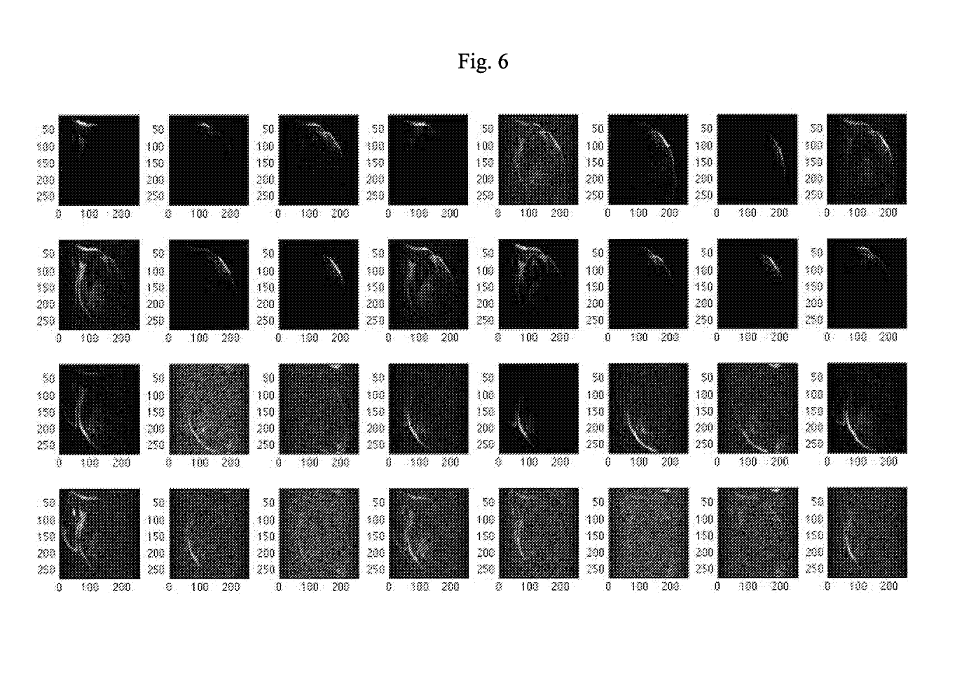

FIG. 7 shows a reduced FOV of the heart. For this purpose, the data set on the right was used. Folding in the image region of the coils, in each instance, is shown with a reduction factor of two.

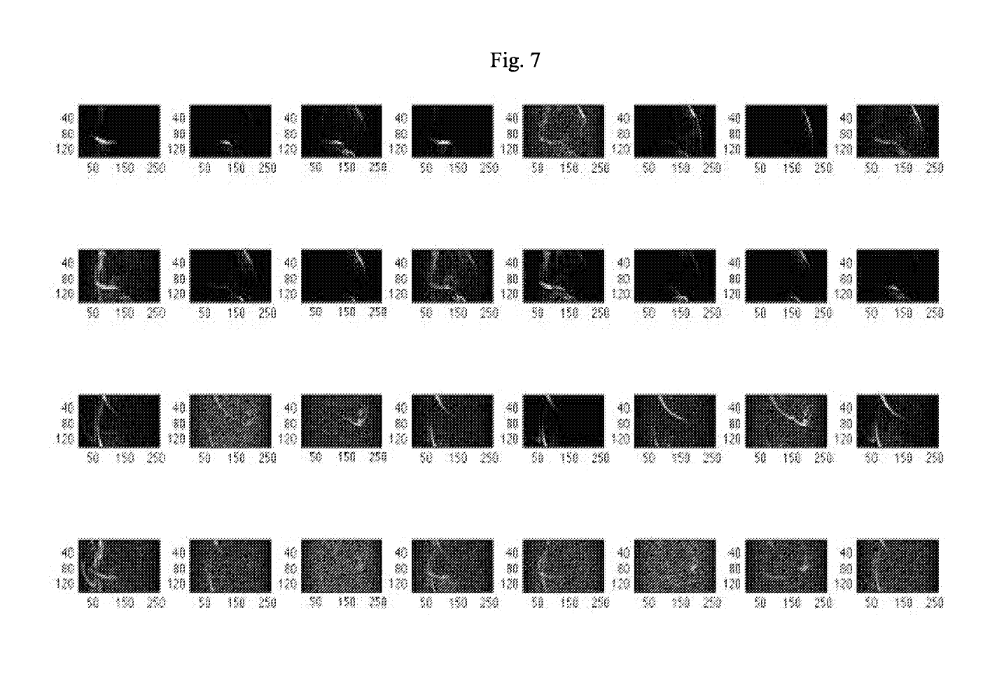

FIG. 8 shows the result after the data set on the right was interpolated and the two data sets underwent the algorithm of the SENSE reconstruction. The image has a resolution of 270×256 pixels and was able to be reconstructed without folding artifacts.

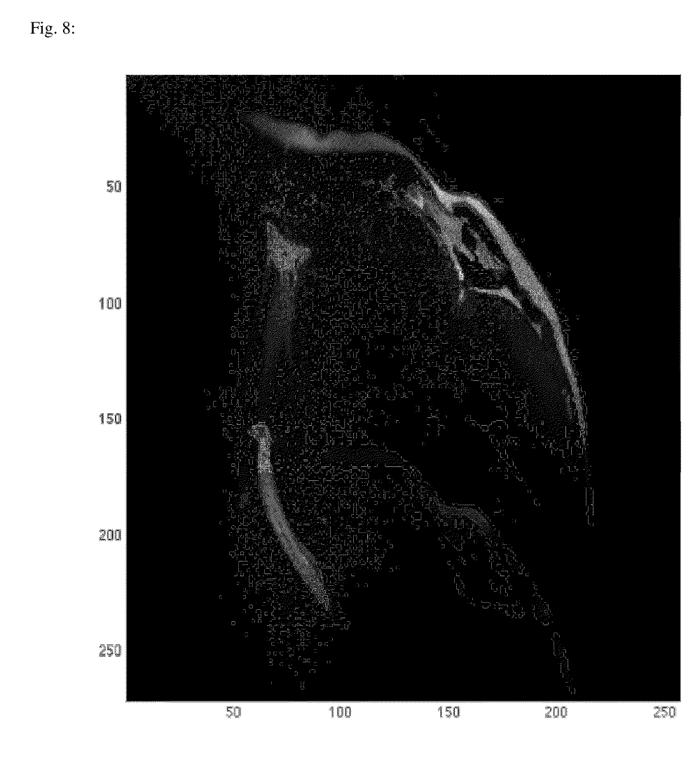

### DESCRIPTION OF VARIOUS AND PREFERRED EMBODIMENTS OF THE INVENTION

Spin-echo particularly describes the re-appearance of the magnetic resonance signal after decay of the FID signal. For this purpose, dephasing of the spin (decay of the transverse magnetization) is cancelled out by introduction of a 180° inversion pulse. The spins get back into phase, and the spin-echo occurs at the time TE (echo time). The FID signal is induced by the HF excitation of the nuclear resonance, and decreases exponentially at a characteristic time constant T2* without externally influences (freely).

In the sense of the invention, the first echo group can also be referred to as Echo 1 (or E1) and the second echo group as Echo 2 (E2).

In current clinical practice, black blood imaging techniques are used to (i) produce images of the morphology and anatomy of the heart and the large blood vessels, (ii) detect edemas, (iii) diagnose amyloidosis, and for (iv) T₂ evaluation and characterization of tissues. However, this technique is slow. The method according to the invention can make imaging significantly faster and can therefore preferably be used for the different black blood MR imaging techniques.

It is preferred that independent phase coding of the echo groups is achieved by means of the implementation of independent gradients along the phase coding direction.

A gradient defines the intensity and direction of the change in a variable in space. A magnetic field gradient is a change in the magnetic field in a specific direction, a linear increase or decrease. The magnetic gradient fields are generated using gradient coils. They determine the spatial resolution in the image, for example.

The use of additional gradients along the reading direction allows differentiation of the two echo groups, so that a first and a second echo group are formed, with the two echo groups being handled separately from one another with regard to data recording, phase coding, and reconstruction.

In the displaced UFLARE approach disclosed in the prior art, an echo group is lost, because an echo group is completely pushed out of the acquisition window as the result of the use of additional gradients along the reading direction (Niendorf, On the application of susceptibility-weighted ultra-fast low-angle RARE experiments in functional MR imaging. Magn Reson Med, 1999. 41(6): p. 1189-98; Norris, Ultrafast Low-Angle Rare-U-Flare. Magnetic Resonance in Medicine, 1991. 17(2): p. 539-542).

In the known split-echo approach, both echo groups undergo the same phase coding (Schick, SPLICE: Sub-second diffusion-sensitive MR imaging using a modified fast spin-echo acquisition made. Magnetic Resonance in Medicine, 1997. 38(4): p. 638-644). It is disadvantageous, in this connection, that the two echo groups are reconstructed independent of one another. To form a final image, the two image results of the independent reconstruction of the two echo groups are simply summarized. In the split-echo approach, the two echo groups undergo equal treatment not only for phase coding but also for reconstruction, and this can be viewed ad disadvantageous for the imaging and particularly for the quality and speed of the imaging.

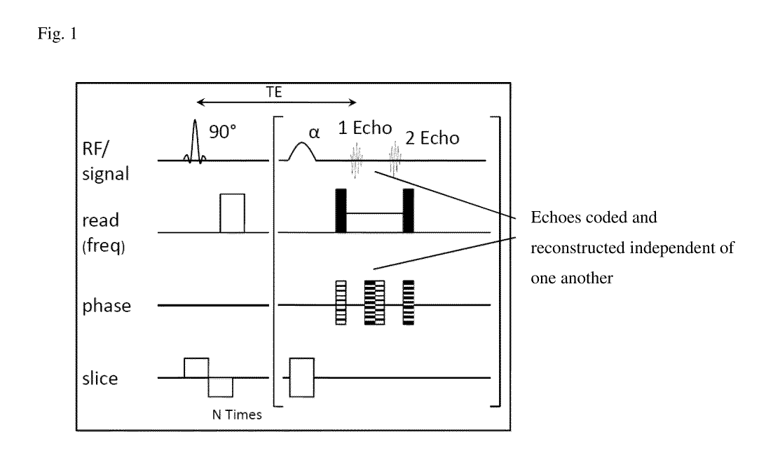

In the preferred embodiment of the invention, the two echo groups (E1, E2) experience phase coding and reconstruction independent of one another (see FIG. 1). Thus, in the case of parallel or accelerated imaging, one of the two echo groups can be used for recording a reference data set or a training data set, while the other echo group is recorded in subsampled manner. The invention is therefore advantageous as compared with the state of the art, because both echo groups are used and provide additional information by means of the different phase coding.

The SCSE-FSE technique also advantageously allows recording trainings or reference data with higher resolution and quality, without having to make time compromises as in the case of separate or conventionally autocalibrating approaches with low location resolution.

It is particularly preferred that one of the two echo groups is used for recording a reference data set or a training data set, and the other echo group is recorded in subsampled manner.

By means of the separation of the echo groups, the reference data set can be recorded and reconstructed at the same time with the data to be reconstructed. No further data recording is necessary to create the reference map.

Advantageously, the reference data set (reference data) or training data set (training data) is recorded at a higher resolution and quality.

It is furthermore preferred that the reference data set or training data set is used for autocalibration.

In this preferred embodiment, the reference or training data (E1) are recorded very close in time and at an interval of only a few milliseconds from the accelerated data (E2). This approach can therefore be used for autocalibration. For this reason, the invention can also be referred to as an autocalibrated split-echo FSE (SCSE-FSE) technique. The subsampled data (E2) can be reconstructed using the reference data, by means of the SENSE or GRAPPA approach, but also with any other form of parallel imaging. It also holds true that temporally subsampled data can be reconstructed using regularly sampled training data, by means of the k-t approach or any other form of reconstruction techniques that preferably utilize spatiotemporal relations or redundancies within a time series.

The method is preferably an autocalibrating approach for recording of reference data for parallel imaging. An advantage is that in this way, the sensitivity with regard to incorrect registration of object positions, organ positions, or artifact susceptibility due to movements between recording of the reference data and of the accelerated data, which is usual for external reference data, is eliminated. The measurements are therefore more precise and informative.

The property of recording regularly sampled central k-space data as reference data and peripherally subsampled k-space data as accelerated data, which is typical for autocalibrating approaches, is eliminated. In the preferred method, reference data and accelerated data are preferably recorded almost synchronously, in terms of time, but independent of one another. As a result, the preferred method has a speed advantage or a signal/noise advantage at the same speed.

By means of the independent phase coding of the two echo groups, the effective data recording rate is doubled. The loss in the signal/noise ratio of the individual echo groups in comparison with the conventional approach can easily be balanced out by the use of acceleration and reconstruction techniques, and therefore offers a speed advantage.

The reference data approach in the sense of the invention can also be referred to as reference data, and the training data approach can be referred to as training data.

It is furthermore preferred that the echo groups are used for generating images with different contrasts or images with the same contrasts but different weightings.

Images with different contrast weighting can be generated by means of a suitable selection of preparation experiment and read-out of the echo groups 1 and 2.

Furthermore, it is preferred that one echo group is used for recording a fat image, and the other echo group is used for recording a water image.

A pure water image represents only the signal component of the protons bound to water in the image, and suppresses the fat component.

A pure fat image represents only the signal component of the protons bound to fat in the image, and suppresses the water component.

By means of this embodiment of the invention, it is possible to conduct MRT methods more quickly, and this means better capacity utilization of the expensive equipment, in terms of time, and therefore reduces costs.

In gradient echo sequences, phase deletions in the image can occur as the result of chemical displacement. The cause is the slight difference in resonance frequencies of fat and water, which lead to a phase shift within a voxel that contains fat/water. In the counter-phase image, contour artifacts are therefore possible at boundary surfaces of tissues that contain fat and water, in terms of the width of a voxel. This chemical displacement, also called chemical shift effect, can be utilized for the method according to the invention.

It is furthermore preferred that one echo group experiences a Cartesian form of phase coding, while the other echo group experiences non-Cartesian forms of phase coding, preferably spiral-shaped, radial, or other arbitrary forms of k-space trajectories.

It is also preferred that one echo group experiences a Cartesian form of phase coding, while the other echo group particularly experiences non-Cartesian forms of phase coding, preferably spiral-shaped, radial, or other arbitrary forms of k-space trajectories, and vice versa.

It is also preferred that one echo group is subsampled and reconstructed by means of parallel imaging, preferably SENSE or GRAPPA.

In the case of SENSE (Sensitivity Encoding), the PAT reconstruction is carried out according to Fourier-Transformation.

GRAPPA (Generalized Autocalibrating Partially Parallel Acquisition) is a further development of SMASH with autocalibration and a modified algorithm for image reconstruction.

In connection with this embodiment, it is preferred that data of the subsampled echo group are reconstructed using the reference data approach or training data approach, by means of parallel imaging, particularly SENSE or GRAPPA. A person skilled in the art knows that known methods of parallel imaging can be used for reconstruction of data.

In contrast to conventional SENSE reconstruction, work is done with two different data sets in the preferred method according to the invention. By separating the echoes, the reference map can be recorded and reconstructed at the same time with the data to be reconstructed. No further data recording is necessary to create the reference map. The image does lose resolution as the result of separation of the echoes of each k-space line. However, the loss occurs in the frequency coding direction, and this can easily be compensated. The sequence can easily be converted from 256×256 to 256×512, without any loss in time.

It is furthermore preferred that the subsampled echo group is reconstructed using regularly sampled training data, by means of the k-t approach or any other form of reconstruction techniques.

It is also preferred that one echo group is used as a navigator echo or phase echo, for recording movements or movement states, while the other echo group serves for collecting image data.

A navigator echo is, in particular, an additional spin or gradient echo for detection of position changes of an object in the measurement volume or other changes.

It is also preferred that one echo group is used to sample specific segments of the k space, while the other echo group samples other segments of the k space. In this way, the quality of the imaging is improved.

It is furthermore preferred that the first echo group represents an odd echo group, and the second echo group represents an even echo group.

In contrast to the state of the art, it is preferred for the method according to the invention that with regard to data recording, phase coding, and reconstruction, the two echo groups are handled independent of one another. The invention has numerous advantages as compared with the state of the art. For example, the data can advantageously be reconstructed with any parallel imaging, e.g. SENSE. For SENSE data sets, SENSE reconstruction is recommended. A complete image is produced from a number of the individual coil images (reference map) and a reduced FOV.

### EXAMPLES

In the following, the invention will be explained using examples and figures, but without being restricted to these.

### Example 1

As exemplary embodiment, the autocalibrated split-echo approach (SCSE FSE) is listed in a preferred embodiment. In this connection, Echo 1 functions as the reference data set, with which the intensity profile of HF coil arrays can be determined. Echo group 2 functions as a subsampled data set. The data set from echo group 2 can be unfolded and reconstructed using the reference data from echo group 1.

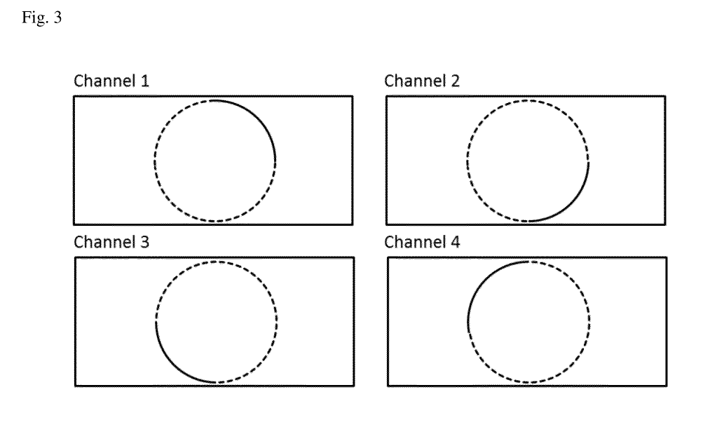

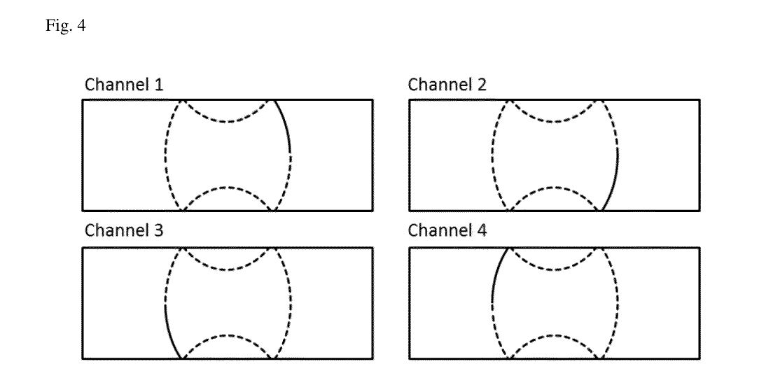

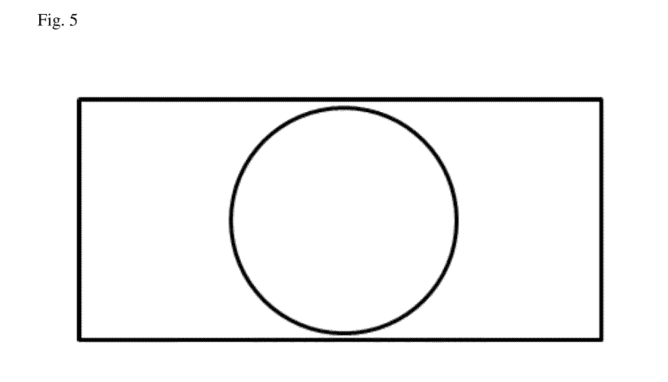

For implementation, independent gradients along the phase coding direction are generated, to separate even and odd echo groups and to code them independent of one another. One echo group serves for the reference map (see FIG. 3). Therefore an external reference scan becomes superfluous. The other echo group serves as the subsampled data set (see FIG. 4). This is unfolded using the reference map. FIG. 5 shows a completely reconstructed image.

The SCSE-FSE sequence was successfully implemented using acceleration factors of up to R=4. Higher acceleration factors can also be achieved. In concrete terms, 18 heartbeats were needed in the implementation, in order to record a slice image with the conventional FSE sequence. For comparison, only five heartbeats were needed at an acceleration factor of R=4, using the SCSE-FSE approach. The SCSE-FSE technique has no influence on blood suppression. The use of the proposed technique is not restricted to MRT of the heart, but can be expanded to cover all desired organs, living beings, objects.

### Example 2

### Heart Data Set for Autocalibrated Split-Echo Fast Spin-Echo Imaging

In the following, a split-echo is reconstructed using the example of the heart. In the reconstruction of the conventional SENSE algorithm, interference patterns that can be seen in the image occur as the result of the offset of the echoes in every k-space line. By means of processing of the raw data, it is possible to separate the echoes in the center of every k-space line. One data set serves as a reference map. The 32 individual coil images have a resolution of 270×256 pixels. The other data set serves for a reduced FOV. After the FOV data set was interpolated, both data sets pass through the algorithm (SENSE reconstruction). The resulting image has a resolution of 270×256 pixels. In this way, it was possible to reconstruct an image without folding artifacts.

For the SENSE reconstruction, the reference map is generated at the same time with the data set to be reconstructed. The two data sets contain different data and are available for reconstruction. Additional data recording for the reference map is no longer required. A complete image was successfully reconstructed.

### Example 3

An autocalibrated split-echo FSE technique with the following data was implemented:

Matrix size=512×526

Echo plus train length: 16

Number of dummy echoes: 8

in-plane resolution: (1.3×1.3) mm²

Slice thickness: 5 mm

TE: 67 ms

Repetition time (Time to Repetition=TR): 1 RR interval

Time between individual 180° refocusing pulses: 4.19 ms

Bandwidth±673 Hz/pixel

By means of additional gradients along the reading direction, even and odd echo groups were separated. The two echo groups were phase-coded differently. With one echo group, reference scans were drawn up, to generate a sensitivity map for the coils. This approach therefore requires no external reference scans and can therefore be referred to as autocalibrating. The second echo group was used to generate a subsampled data set. Acceleration factors from R=2 to R=4 were used. The SCSE-FSE imaging module was [word/words missing] with double IR (double inversion recovery) for suppression of the blood component and triple IR for suppression of the blood/fat component.

The imaging was [word/words missing] with a 3.0 T whole body system (Siemens Verio, Siemens Healthcare, Erlangen, Germany) and a body coil for TX and a 32-channel cardio-coil array (IN VIVO Corp., Gainesville, USA) for RX. Data acquisition was performed during the diastole. The SENSE reconstruction was carried out to unfold the subsampled data sets.

### Example 4

Two data sets are generated using the read-in function: reference map and reduced FOV. For data recording, a spherical phantom was used. Because of the reduction factor of only two, only every other k-space line is recorded. Folding occurs in the image region. After the reduced FOV was drawn up, interpolation to produce a complete FOV takes place. The original matrix size is restored, and can pass through the SENSE algorithm with the reference map and the reduction factor.

Using the complete FOV, a sampling vector of the k space is created with the function “pmri_sample_vector”. The function “pmri_prep” needs this sampling vector, the reference map and the reduced FOV. This function serves for preparation of the data for the SENSE reconstruction. The data are leveled and interpolated. As output, the function generates: a transformed and folded single-coil image, a sensitivity profile of the individual coil images, a covariance matrix.

In conclusion, the SENSE reconstruction takes place with the “pmri_core” function. The image was reconstructed, using the SENSE method, to produce a complete image.

Those skilled in the art will recognize, or be able to ascertain using no more than routine experimentation, many equivalents to the specific embodiments of the invention described herein. Such equivalents are intended to be encompassed by the following claims.

What we claim is:

1. A magnetic resonance tomography method, wherein
a) after basic excitation and a series of high-frequency refocusing pulses according to the spin-echo principle, two echo groups occur, wherein
b) the two echo groups are phase-coded independent of one another, and wherein
c) reconstruction takes place for the two echo groups, independent of one another.

2. The method according to claim 1, wherein
the independent phase coding of the echo groups is achieved via implementation of independent gradients along the phase coding direction.

3. The method according to claim 1, wherein
one of the two echo groups is used for recording a reference data set or a training data set, and the other echo group is recorded in subsampled manner.

4. The method according to claim 3, wherein
the reference data set or training data set is used for autocalibration.

5. The method according to claim 1, wherein
the echo groups are used to generate images having different contrasts or images having the same contrasts with different weighting.

6. The method according to claim 1, wherein
one echo group is used to record a fat image, and the other echo group is used to record a water image.

7. The method according to claim 4, wherein
one echo group is used to record a fat image, and the other echo group is used to record a water image.

8. The method according to claim 1, wherein
one echo group experiences a Cartesian form of phase coding, while the other echo group experiences non-Cartesian forms of phase coding.

9. The method according to claim 8, wherein
the non-Cartesian forms of phase coding are spiral-shaped, radial or other arbitrary forms of k-space trajectories.

10. The method according to claim 4, wherein
one echo group experiences a Cartesian form of phase coding, while the other echo group experiences non-Cartesian forms of phase coding.

11. The method according to claim 10, wherein
the non-Cartesian forms of phase coding are spiral-shaped, radial or other arbitrary forms of k-space trajectories.

12. The method according to claim 5, wherein
one echo group experiences a Cartesian form of phase coding, while the other echo group experiences non-Cartesian forms of phase coding.

13. The method according to claim 12, wherein
the non-Cartesian forms of phase coding are spiral-shaped, radial or other arbitrary forms of k-space trajectories.

14. The method according to claim 1, wherein
one echo group is subsampled and reconstructed via parallel imaging.

15. The method according to claim 14, wherein the parallel imaging is SENSE or GRAPPA.

16. The method according to claim 14, wherein
the subsampled echo group is reconstructed using regularly sampled training data via k-t approach or any other form of reconstruction technique.

17. The method according to claim 1, wherein
one echo group is used as a navigator echo or phase echo for recording movements or movement states, while the other echo group serves for the collection of image data.

18. Method according to claim 1, wherein
one echo group is used to sample specific segments of the k space, while the other echo group samples other segments of the k space.

19. Method according to claim 1, wherein
the first echo group is an odd echo group, and the second echo group is an even echo group.
